(19) United States
(12) Patent Application Publication
(10) Pub. No.: US 2024/0387379 A1
(43) Pub. Date: Nov. 21, 2024

(54) METHOD AND APPARATUS FOR COPPER PLATING IN SEMICONDUCTOR DEVICES

(71) Applicant: Taiwan Semiconductor Manufacturing Company, Ltd., Hsinchu (TW)

(72) Inventors: Jun-Nan NIAN, Tainan City (TW); Chun-Ju WU, Tainan City (TW); Jian-Shin TSAI, Tainan City (TW); Yao-Hsiang LIANG, Shinchu (TW); Ming-Ching CHUNG, Tainan City (TW)

(21) Appl. No.: 18/318,537

(22) Filed: May 16, 2023

(51) Int. Cl. H01L 23/532; H01L 21/768

(52) U.S. Cl. CPC H01L 23/53238; H01L 21/76846; H01L 21/76873; H01L 21/76807

(57) ABSTRACT

Some implementations described herein provide techniques and apparatuses for forming a copper structure adjacent to a multi-layer film structure included in a semiconductor device. The techniques include using an electroplating process to form the copper structure adjacent to the multi-layer film structure, wherein a pre-layer of chlorine molecules coats a seed layer of the multi-layer film structure during the electroplating process. During formation of the copper structure, a chlorine-enriched interface region (e.g., a control layer including a copper chelate material with chlorine) may be formed between the copper structure and the multi-layer film structure including the seed layer. The chlorine-enriched interface region may reduce a likelihood of electromigration and/or stress migration within the semiconductor device.

### BACKGROUND

Some electronic devices, such as a processor, a memory device, or another type of electronic device, include a middle end of line (MEOL) region that electrically connects transistors in a front end of line (FEOL) region to a back end of line (BEOL) region. The BEOL region or MEOL region may include a dielectric layer and via plugs formed in the dielectric layer. A plug may include one or more metals for electrical connection.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of tools in an example environment in which systems and/or methods described herein may be implemented.

FIG. 2 is a diagram of a portion of an example device described herein.

FIGS. 3A and 3B are diagrams of example implementations of conductive structures described herein.

FIGS. 4A-4G are diagrams of an example process used to form conductive structures described herein.

FIGS. 5A-5G are diagrams of an example semiconductor manufacturing process used to form conductive structures described herein.

FIGS. 6A-6C are diagrams of an example details related to formation of a chlorine-enriched interface region described herein.

FIG. 7 diagram of an example copper pattern within a chlorine-enriched interface region described herein.

FIGS. 8A and 8B are diagrams of an example implementation described herein.

FIG. 9 is a diagram of an example implementation described herein.

FIG. 10 is a diagram of example components of a device described herein.

FIG. 11 is a flowchart of an example process associated with copper plating in semiconductor devices.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, copper (Cu) is used for back end of line (BEOL) metallization layers and vias (also referred to as M1, M2, . . . or Mx (x may be a positive integer) interconnects or metallization layers) or for middle end of line (MEOL) contact plugs (also referred to as M0 interconnects or metallization layers) due to low contact resistance and sheet resistance relative to other conductive materials, such as aluminum (Al). Lower resistivity provides lower resistance/capacitance (RC) time constants and faster propagation of signals across an electronic device. However, copper also has a high diffusion rate, which can cause copper ions to diffuse into surrounding dielectric material. This diffusion results in an increase in resistivity for BEOL metallization layers and vias. Increased resistivity can decrease electrical performance of an electronic device. Moreover, diffusion may result in copper ions migrating into other BEOL layers, middle end of line (MEOL) layers, and/or front end of line (FEOL) layers, such as source or drain interconnects (also referred to as source/drain vias or VDs) and/or gate interconnects (also referred to as gate vias or VGs), which can cause semiconductor device failures and reduced manufacturing yield.

Some implementations described herein provide techniques and apparatuses for forming a copper structure adjacent to a multi-layer film structure included in a semiconductor device. The techniques include using an electroplating process to form the copper structure adjacent to the multi-layer film structure, where a pre-layer of chlorine molecules coats a seed layer of the multi-layer film structure during the electroplating process. During formation of the copper structure, a chlorine-enriched interface region (e.g., a control layer including a copper chelate material with chlorine) may be formed between the copper structure and the multi-layer film structure including the seed layer.

Based on a presence of the chlorine molecules within the interface region, a magnitude of an energy absorption level may be increased relative to an interface region including pure copper. The increased magnitude of the energy absorption level may reduce a likelihood of diffusion of the copper ions (through either electromigration (EM) or stress migration (SM)) through the multi-layer film structure and to other metallization layers of the semiconductor device (e.g., MEOL metallization layers and/or FEOL metallization layers). Additionally, or alternatively and during formation of the copper structure, the presences of the chlorine-enriched interface region may improve electromigration of copper ions within the copper structure to reduce voids and/or defects within the copper structure.

In this way, a likelihood of unintended migration of copper ions from the copper structure to MEOL and/or BEOL structures may be reduced to increase an electrical performance of the semiconductor device. Additionally, or alternatively, a likelihood of voids and/or defects within the copper structure may be reduced to increase a reliability of the semiconductor device. As such, an amount of resources used to manufacture a volume of the semiconductor device satisfying a performance and reliability threshold (semiconductor processing tools, raw materials, manpower, and/or computing resources, among other examples) may be reduced.

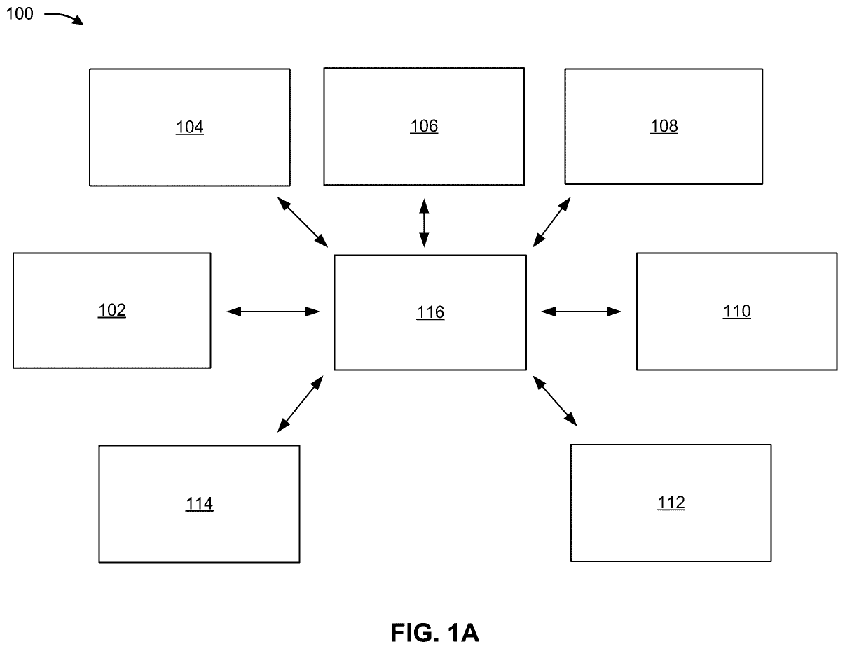

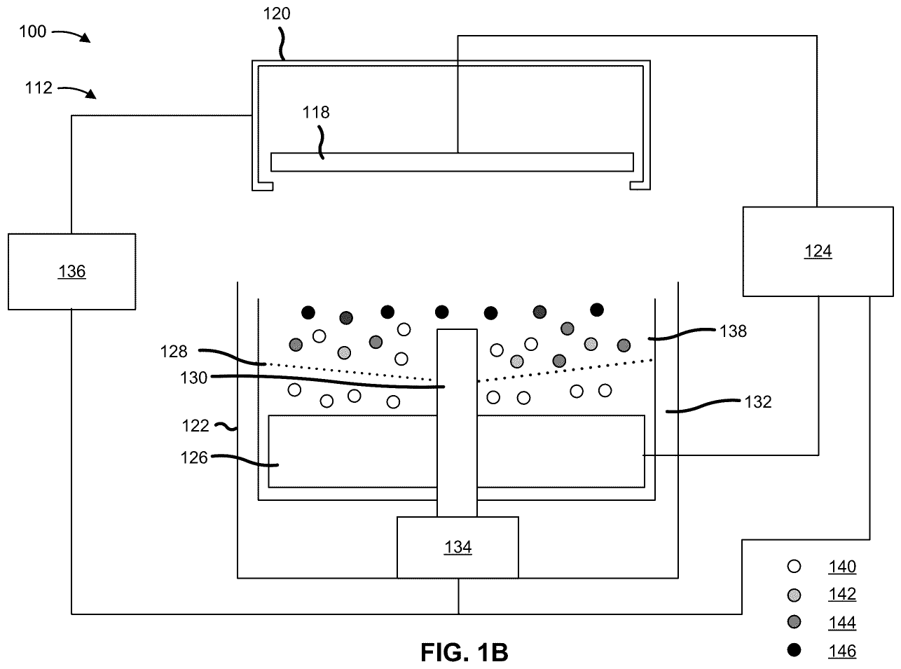

FIGS. 1A and 1B are diagrams of tools in an example environment 100 in which systems and/or methods described herein may be implemented. The example environment 100 includes semiconductor processing tools that can be used to form semiconductor structures and devices, such as a conductive structure as described herein.

As shown in FIG. 1A, the environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 may include a chemical vapor deposition (CVD) tool, such as a plasma-enhanced CVD (PECVD) tool, a high-concentration plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or another type of exposure tool. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or another type of etch tool. In some implementations, the etch tool 108 includes a chamber that is filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 includes a mobile robot, a robot arm, a tram or rail car, an overhead hoist transfer (OHT) vehicle, an automated material handling system (AMHS), and/or another type of tool that is used to transport wafers and/or dies between semiconductor processing tools 102-114 and/or to and from other locations such as a wafer rack, a storage room, or another location. In some implementations, the wafer/die transport tool 116 is a programmed tool to travel a particular path and/or may operate semi-autonomously or autonomously.

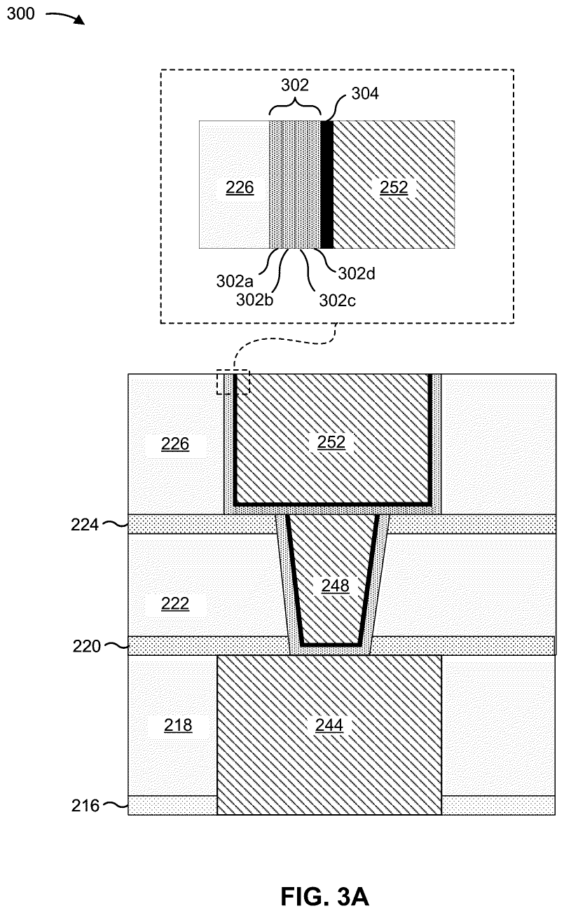

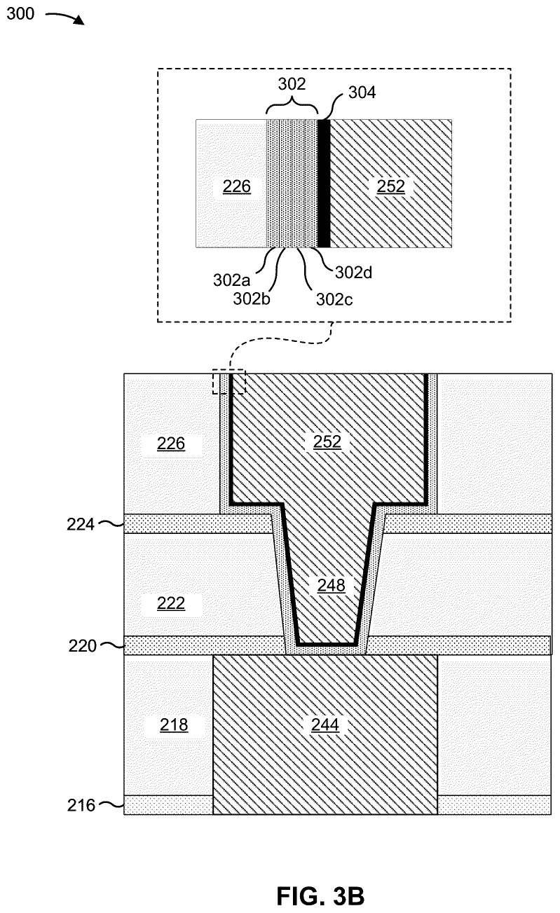

As described in greater detail in connection with FIGS. 3A-10, and elsewhere herein, the sing tools 102-114 and/or the wafer/die transport tool 116 may form a conductive structure within a semiconductor device using a damascene process. A damascene process is a series of operations in which a recess is formed within dielectric layers of a semiconductor device. The recess is then filled with a metal material (e.g., electroplated with copper), followed by a planarization of the metal material to form a conductive structure within the dielectric layers. Through use of the damascene process, etching of the metal material to form the conductive structure may be avoided, thereby reducing a likelihood of damage to the conductive structure.

In some implementations, the damascene process corresponds to a single damascene process, in which the recess for the conductive structure is formed through a single patterning and etching operation. In such implementations, the conductive structure formed in the recess may correspond to a single damascene structure having a single damascene profile (e.g., a conductive structure with opposing sides having a continuous, smooth edges).

In some implementations, the damascene operation corresponds to a multi-damascene operation, in which the recess for the conductive structure is formed through multiple patterning and etching operations. In such implementations, the conductive structure formed in the recess may correspond to a multi-damascene structure having a multi-damascene profile (e.g., a conductive structure with opposing sides having a tiered or stepped edges).

FIG. 1B shows additional details of the plating tool 112. The plating tool 112 may include a tool that plates a semiconductor substrate 118 (e.g., a wafer, an insulating wafer, and/or another type of wafer). As shown in FIG. 1B, the plating tool includes a semiconductor substrate holder 120, a plating bath 122, a power supply 124, an anode 126, a plating membrane 128, a nozzle 130, one or more return lines 132, a pump 134, and a controller 136.

The semiconductor substrate holder 120 is capable of holding the semiconductor substrate 118 during a plating process. In some implementations, the semiconductor substrate holder 120 may lower the semiconductor substrate 118 into the plating bath 122, which may be a chamber that is filled with a plating solution 138. The plating solution 138 may be a liquid containing a plating material 140, an accelerator additive 142, and a suppressor additive 144.

The power supply 124 may be a direct current (DC) power supply that is connected to the anode 126 and the semiconductor substrate 118 via leads and may apply a voltage across the anode 126 and the semiconductor substrate 118 to cause the anode 126 to be oxidized and to release the plating material 140 into the plating solution 138.

The plating membrane 128 may reduce and/or prevent the accelerator additive 142 and/or the suppressor additive 144 from traveling through the plating solution 138 and reaching the anode 126. The plating membrane 128 may further permit the plating material 140 released from the anode 126 to travel toward the semiconductor substrate 118.

The nozzle 130 includes an elongated cylindrical structure or another type of elongated structure to direct the flow of the plating solution 138 toward the semiconductor substrate 118. In some implementations, the nozzle 130 may dispense the plating solution 138 provided via the one or more return lines 132. In this way, the plating solution 138 may be circulated through the plating bath 122 and reused. The pump 134 includes any one of various types of pumps that are capable of pumping a liquid from the one or more return lines 132 and through the nozzle 130.

The controller 136 may include a processor, a computer (e.g., a desktop computer, a laptop computer, a tablet computer, a server, and/or the like), and/or another device capable of controlling various devices and/or components of the plating tool 112. For example, the controller 136 may be connected to the power supply 124, and is capable of causing the power supply 124 to apply a voltage across the anode 126 and the semiconductor substrate 118, is capable of causing the power supply 124 to stop applying a voltage across the anode 126 and the semiconductor substrate 118, is capable of changing the voltage applied by the power supply 124, and/or the like.

As another example, the controller 136 may be connected to the pump 134 and may cause the pump 134 to pump the plating solution 138 from the one or more return lines 132 to the nozzle 130, may cause the pump 134 to stop pumping the plating solution 138, may adjust the speed or rate at which the plating solution 138 is pumped through the nozzle 130, and/or the like. As another example, the controller 136 may be connected to the semiconductor substrate holder 120 and may cause the semiconductor substrate holder 120 to lower the semiconductor substrate 118 into the plating bath 122, may cause the semiconductor substrate holder 120 to rotate the semiconductor substrate 118 while the semiconductor substrate 118 is at least partially submerged in the plating bath 122 (e.g., to increase the coverage and uniformity of plating material 140 on the semiconductor substrate 118), may cause the semiconductor substrate holder 120 to raise the semiconductor substrate 118 out of the plating bath 122, may vary a rate at which the semiconductor substrate 118 is lowered into the plating bath 122, and/or the like.

The plating material 140, and/or the anode 126, may include various types of conductive materials, metals, and/or the like. For example, the plating material 140 and/or the anode 126 may include a copper material (Cu). Alternatively, the plating material 140 and/or the anode 126 may include an aluminum material (Al), a nickel material (Ni), a tin material (Sn), a tin-lead material SnPb), a tin-silver material (SnAg), and/or another type of material.

The accelerator additive 142 may include a bis (3-sulfopropyl) disulfide accelerator (e.g., an SPS accelerator), among other examples. Additionally, or alternatively, the suppressor additive 144 may include a polyethylene glycol suppressor (e.g., a PEG suppressor), among other examples. Different concentrations of the accelerator additive 142 and/or the suppressor additive 144 in the plating solution 138 may be used to increase or decrease deposition rates of the plating material 140 on the semiconductor substrate 118, reduce a surface roughness of the plating material 140 deposited onto the semiconductor substrate 118, and/or the like.

In some implementations, and as shown in FIG. 1B, the plating solution 138 includes chlorine molecules 146 that are suspended in the plating solution 138 near a surface of the plating solution 138. As the semiconductor substrate 118 is lowered into in the plating solution 138 (e.g., immersed or submerged into the plating solution 138), the chlorine molecules 146 may form a pre-layer (a pre-layer of the chlorine molecules 146) on surfaces of the semiconductor substrate 118.

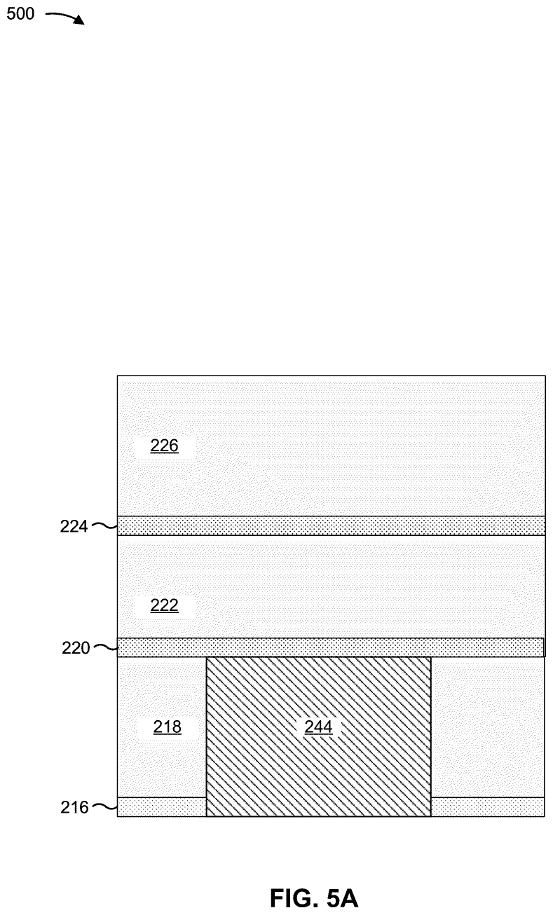

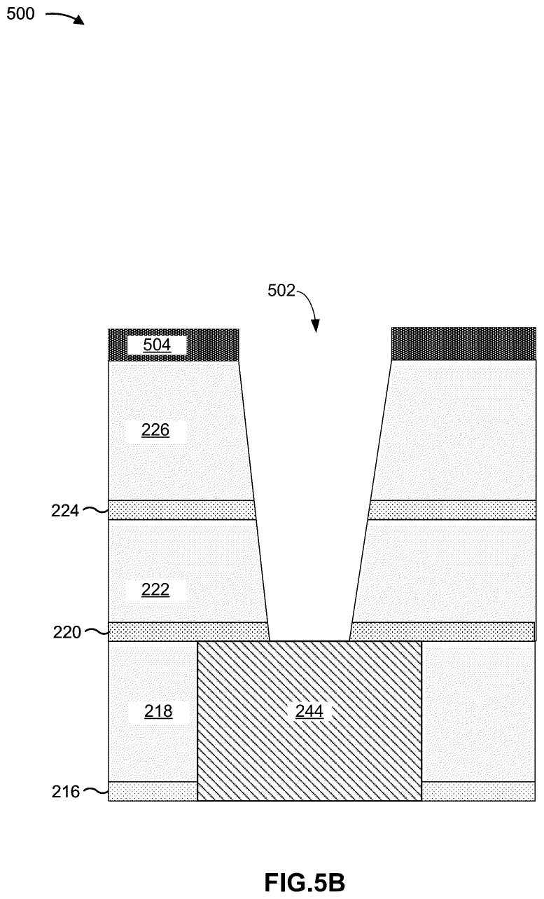

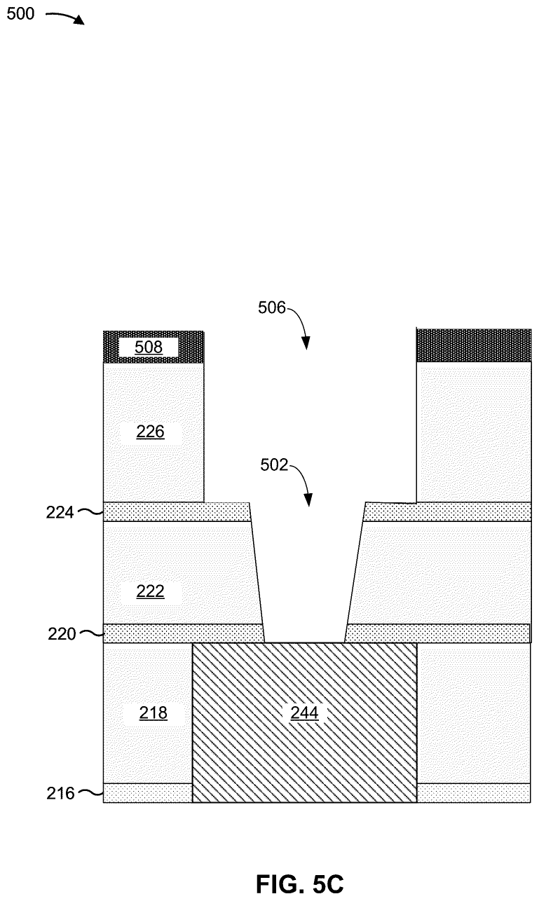

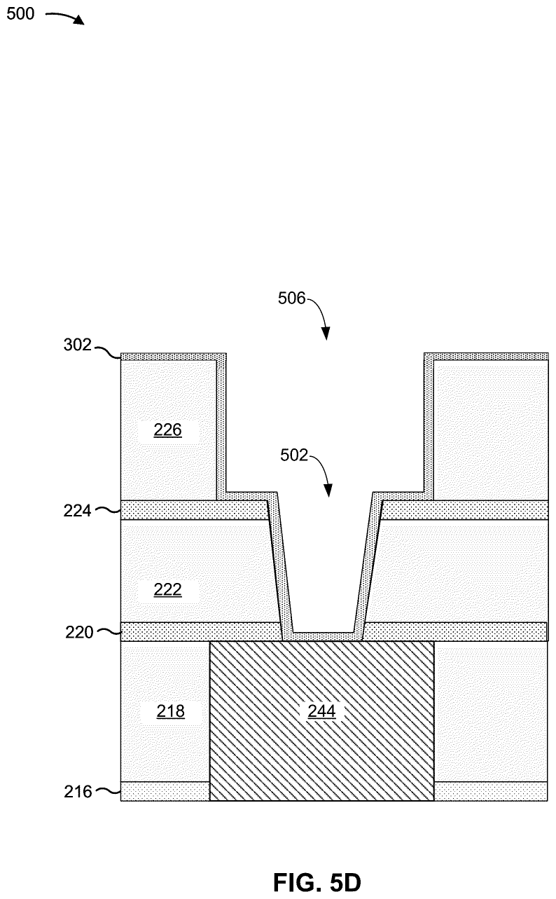

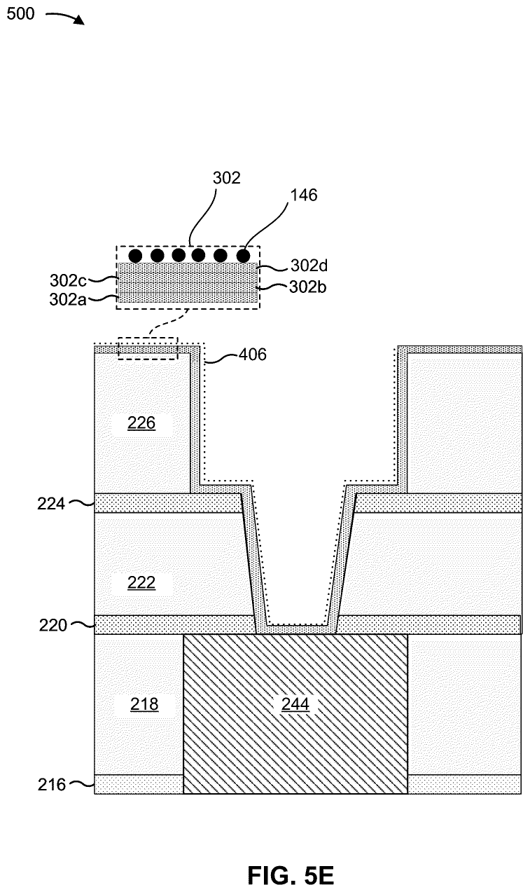

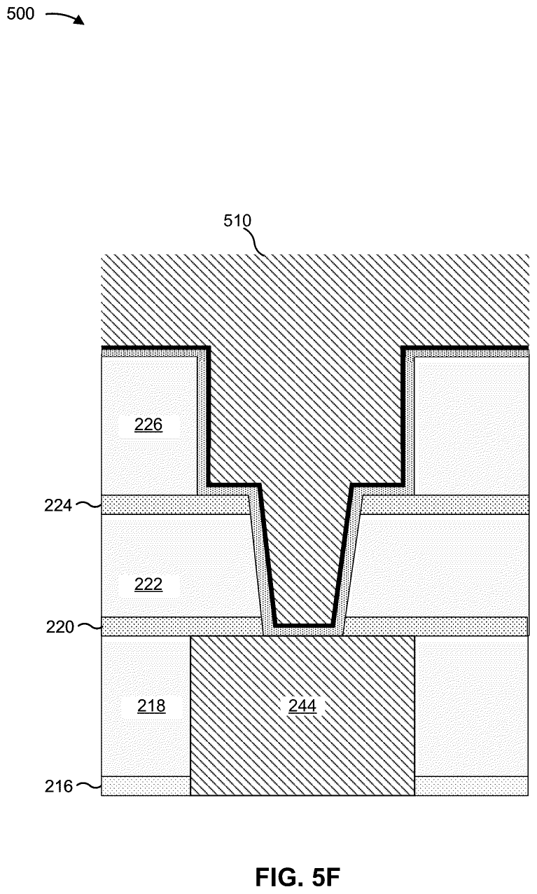

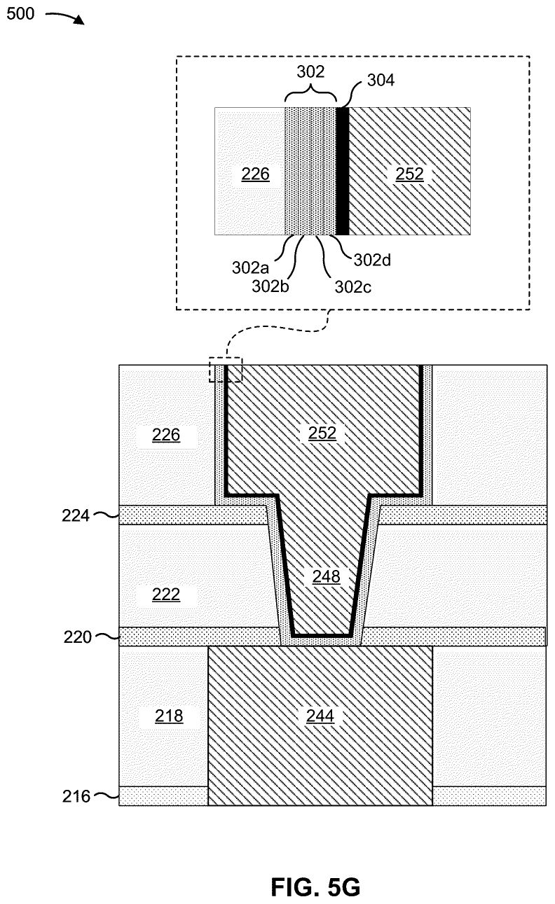

As described in greater detail in connection with FIGS. 5A-8B and elsewhere herein, the pre-layer of the chlorine molecules 146 on the surface of the semiconductor substrate 118, in combination with the accelerator additive 142 and/or the suppressor additive 144, may chelate the plating material 140 during an electroplating process. The chelation of the plating material 140 may cause a chlorine-enriched interface region within an electroplated structure that is being formed on the semiconductor substrate 118 during the electroplating process.

The chlorine-enriched interface region may reduce a likelihood of subsequent electromigration and/or stress migration of ions from the electroplated structure to other structures formed on or within the semiconductor substrate 118. Furthermore, a rate at which the semiconductor substrate 118 passes through the chlorine molecules 146 suspended at the surface of the plating solution 138 may be varied to satisfy an electromigration threshold or to satisfy a stress migration threshold.

In this way, a likelihood of unintended migration of ions from the electroplated structure may be reduced to increase an electrical performance of a semiconductor device including the electroplated structure. Additionally, or alternatively, a likelihood of voids and/or defects within the structure may be reduced to increase a reliability of the semiconductor device. As such, an amount of resources used to manufacture a volume of the semiconductor device satisfying a performance and reliability threshold (semiconductor processing tools, raw materials, manpower, and/or computing resources, among other examples) may be reduced.

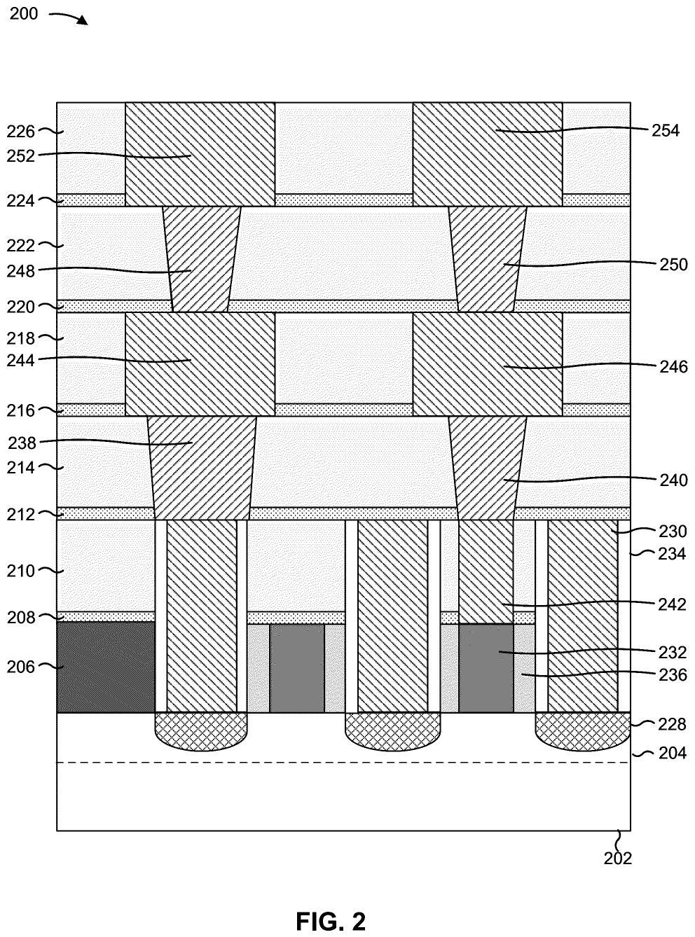

One or more of the semiconductor processing tools 102-114 and/or the wafer/die transport tool 116 of FIGS. 1A and 1B may perform a series of operations. For example, and as described in greater detail in connection with FIGS. 2-10 and elsewhere herein, the series of operations includes forming a conductive layer of a semiconductor device. The series of operations includes forming one or more dielectric layers over the conductive layer. The series of operations includes forming a recess within the one or more dielectric layers. The series of operations includes forming a multi-layer film structure that includes one or more barrier layers and a copper seed layer on the one or more barrier layers within the recess. The series of operations includes forming a copper structure including a chlorine-enriched interface region on the multi-layer film structure.

The number and arrangement of tools shown in FIGS. 1A and 1B are provided as one or more examples. In practice, there may be additional tools, fewer tools, different tools, or differently arranged tools than those shown in FIGS. 1A and 1B. Furthermore, two or more tools shown in FIGS. 1A and 1B may be implemented within a single tool, or a single tool shown in FIGS. 1A and 1B may be implemented as multiple, distributed tools. Additionally, or alternatively, a set of tools (e.g., one or more tools) of environment 100 may perform one or more functions described as being performed by another set of tools of environment 100.

FIG. 2 is a diagram of a portion of an example device 200 described herein. Device 200 includes an example of a memory device, a logic device, a processor, an input/output device, and/or another type of semiconductor device that includes one or more transistors.

The device 200 may include a substrate 202, an active layer, and one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the device 200. The dielectric layers 206, 210, 214, 218, 222, and 226 may include a silicon nitride (SiNₓ), an oxide (e.g., a silicon oxide (St& s) and/or another oxide material), and/or another type of dielectric material. The ESLs 208, 212, 216, 220, and 224 includes a layer of material that is configured to permit various portions of the device 200 (or the layers included therein) to be selectively etched or protected from etching to form one or more of the structures included in the device 200. For example, the ESLs 208, 212, 216, 220, and 224 may each include silicon nitride (SiNₓ), an oxide (e.g., a silicon oxide (SiOₓ), silicon oxynitride (SiOₓNₓ) metal oxide, and/or metal oxynitride.

As an example in FIG. 2, the device 200 may include a plurality of epitaxial (epi) regions 228 that are grown and/or otherwise formed on and/or around portions of a fin structure 204 of the substrate 202. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source or drain regions of the transistors included in the device 200.

The epitaxial regions 228 are electrically connected to metal source or drain contacts 230 of the transistors included in the device 200. The metal source or drain contacts (MDs) 230 include cobalt (Co), ruthenium (Ru), and/or another conductive or metal material. The transistors further include gates 232, which are formed of a polysilicon material, a metal (e.g., tungsten (W) or another metal), and/or another type of conductive material. In some implementations, the gates 232 may comprise multiple layers of material, such as multiple layers of metal or multiple layers including at least one polysilicon layer and at least one metal layer, among other examples. The metal source or drain contacts 230 and the gates 232 are electrically isolated by one or more sidewall spacers, including spacers 234 on each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gates 232 are electrically connected to one or more types of interconnects. The interconnects electrically connect the transistors of the device 200 and/or electrically connect the transistors to other areas and/or components of the device 200. In some implementations, the interconnects electrically connect the transistors to a back end of line (BEOL) region of the device 200.

The metal source or drain contacts 230 are electrically connected to source or drain interconnects 238 (e.g., source or drain vias or VDs). One or more of the gates 232 are electrically connected to gate interconnects 240 (e.g., gate vias or VGs). The interconnects 238 and 240 include a conductive material such as tungsten, cobalt, ruthenium, copper, and/or another type of conductive material. In some implementations, the gates 232 are electrically connected to the gate interconnects 240 by gate contacts 242 (CB or MP) to reduce contact resistance between the gates 232 and the gate interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of MEOL and BEOL layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes conductive structures 248 and 250 (e.g., via structures). The V0 via layer is electrically connected to an M1 metallization that includes conductive structures 252 and 254. In some implementations, the BEOL layers of the device 200 include additional metallization layers and/or vias that connect the device 200 to a package.

As described in greater detail in connection with FIGS. 3A-10, and elsewhere herein, a conductive structure (the conductive structure 248, among other examples,) may be a copper structure formed using electroplating techniques described herein. Furthermore, the conductive structure may include a single damascene profile or a dual-damascene profile. Furthermore, the conductive structure may include a chlorine-enriched interface region that joins with a barrier layer structure that is adjacent to the conductive structure.

As indicated above, FIG. 2 is provided as an example. Other examples may differ from what is described with regard to FIG. 2.

FIGS. 3A and 3B are diagrams of example implementations 300 of conductive structures described herein. FIGS. 3A and 3B show side views of portions of the device 200 including the dielectric layers 218, 222, and 226, the ESLs 216, 220, and 224, and the conductive structures 244, 248, and 252.

FIGS. 3A and 3B further include a multi-layer film structure 302. The multi-layer film structure 302 may include barrier layers 302a-302c and seed layer 302d. The barrier layer 302a may include a layer of a silicon dioxide material (SiO₂), among other examples. The barrier layer 302b may include a layer of a tantalum nitride material (TaN), among other examples. The barrier layer 302c may include a layer of a cobalt material (Co), among other examples. However, other materials for the barrier layers 302a-302c are within the scope of the present disclosure.

The seed layer 302d may include a layer of a copper material (Cu) that promotes growth of conductive structures within the device 200 during an electroplating operation. However, other materials for the seed layer 302d are within the scope of the present disclosure.

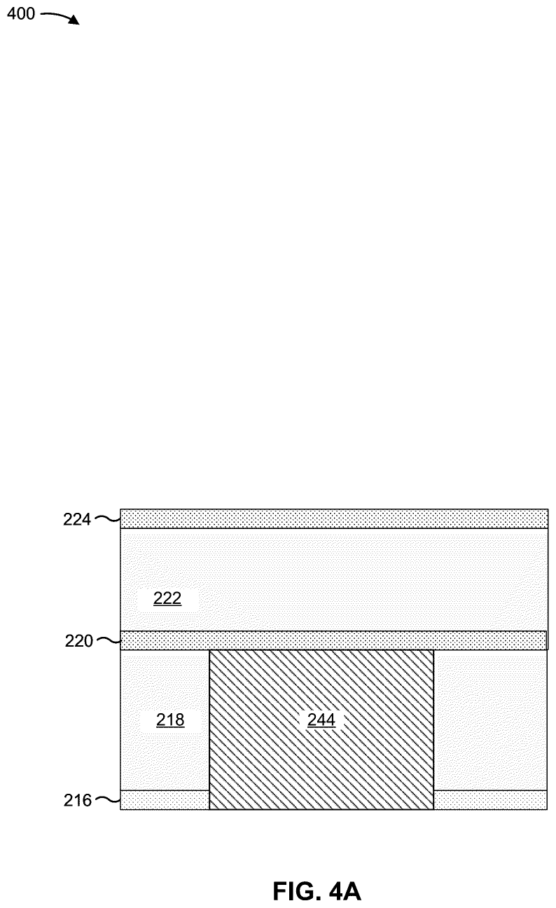

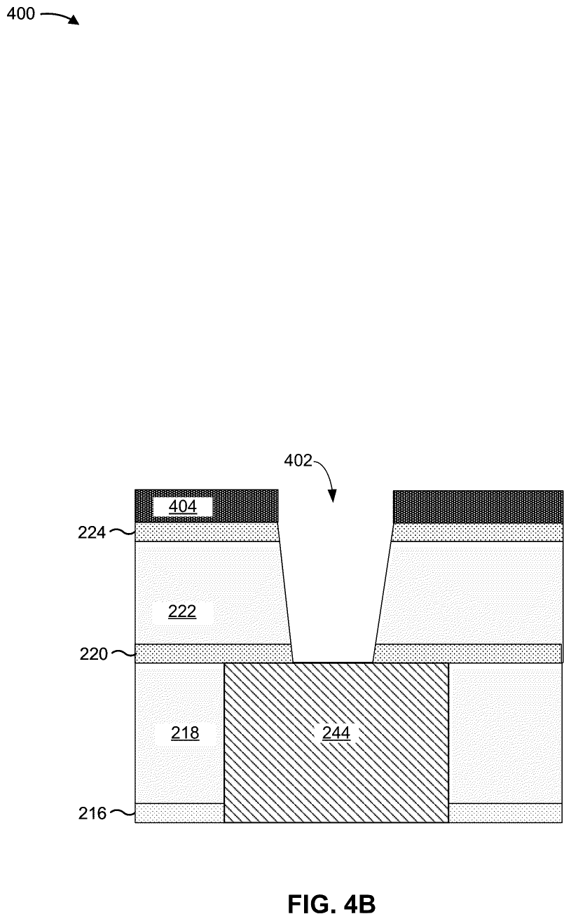

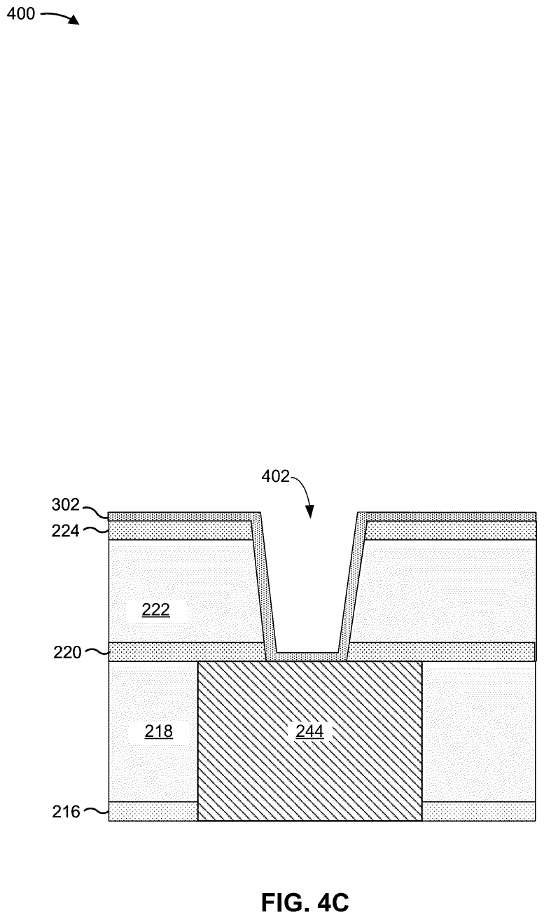

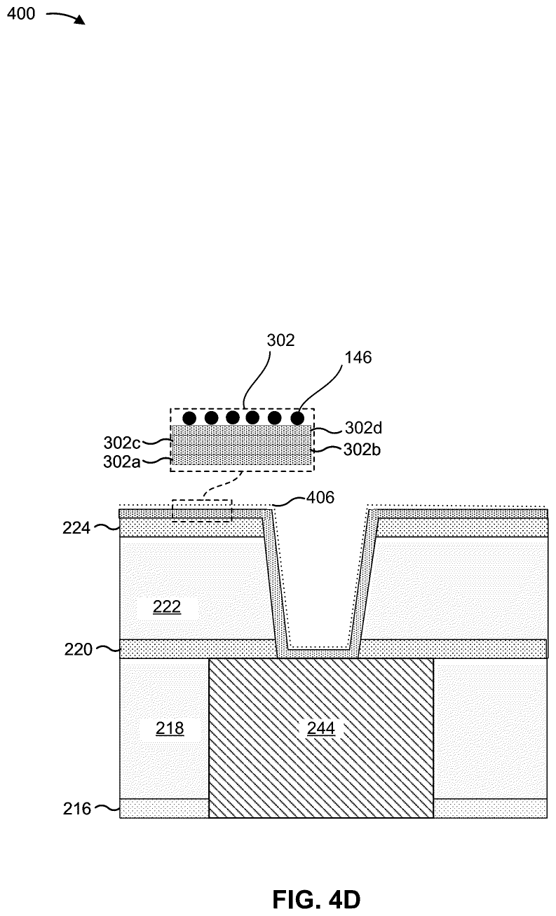

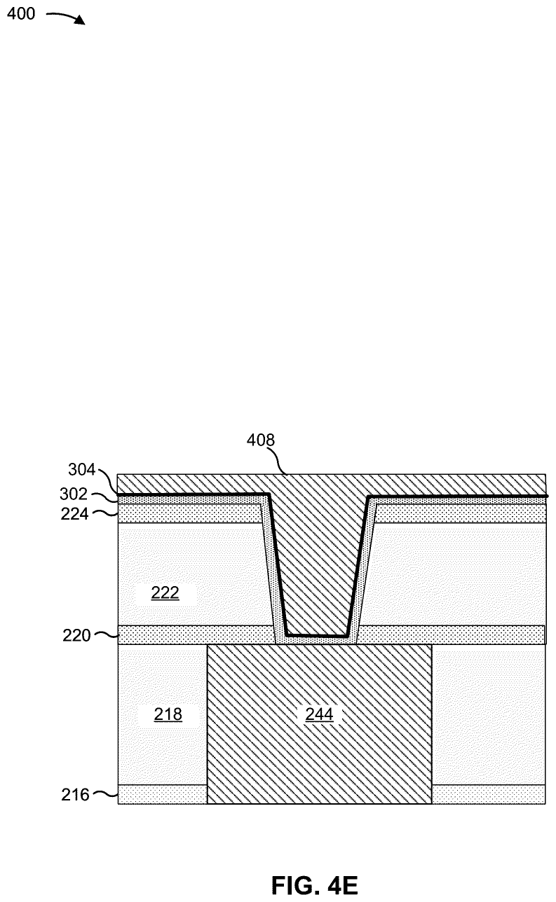

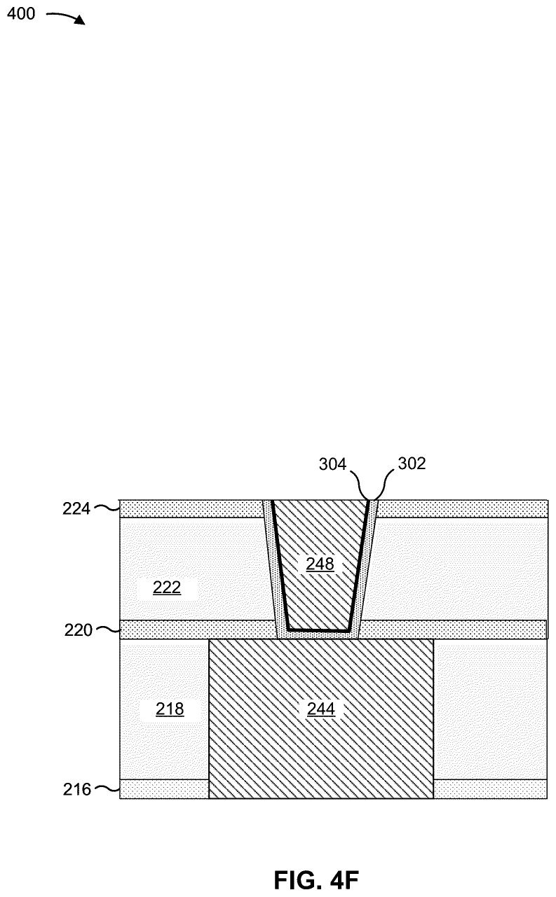

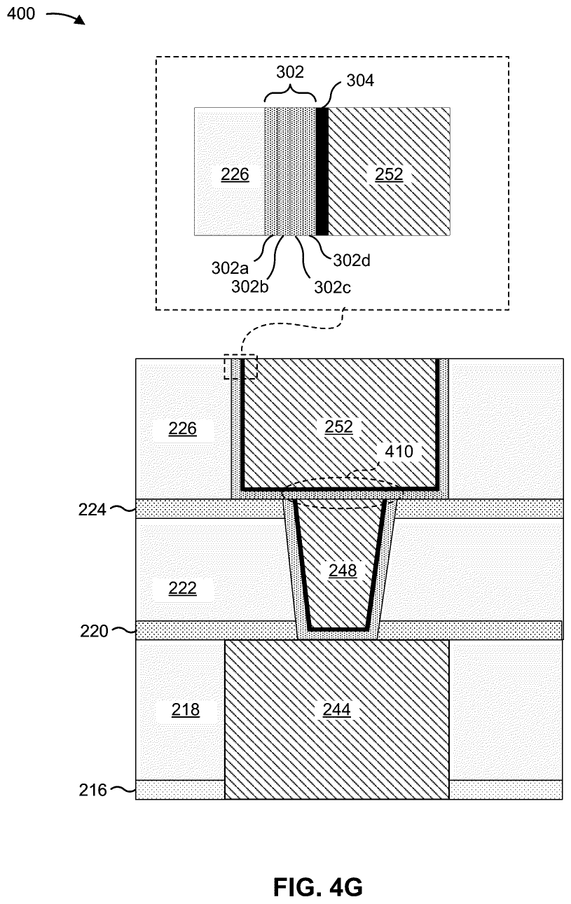

As further shown in FIGS. 3A and 3B, the conductive structures 248 and 252 include an interface region 304 (e.g., sometimes referred to as a control layer) that interfaces the conductive structures 248 and 252 with the multi-layer film structure 302 (e.g., on the seed layer 302d). As described in greater detail in connection with FIGS. 4A-10, and elsewhere herein, the interface region 304 may correspond chlorine-enriched interface regions of the conductive structures 248 and 252, in which chelated copper is formed during an electroplating process.

In FIG. 3A, and as describe in greater detail in connection with FIGS. 4A-4G, the conductive structures 248 and 252 are each formed using a single damascene process. As shown in FIG. 3A, the semiconductor device (e.g., the device 200) includes a conductive layer (e.g., the conductive structure 244). The semiconductor device includes one or more dielectric layers (e.g., the dielectric layers 222 and 226) over the conductive layer. The semiconductor device includes a multi-layer film structure (e.g., a multi-layer film structure 302) that conforms to a single damascene profile (a single damascene profile of the conductive structures 248 and/or 252) within the one or more dielectric layers. The multi-layer film structure includes one or more barrier layers (e.g., the barrier layers 302a-302c) and a copper seed layer (e.g., the seed layer 302d) on the one or more barrier layers. The semiconductor device includes a copper structure (e.g., the conductive structure 248 and/or the conductive structure 252) that is adjacent to the multi-layer film structure and that includes a chlorine-enriched interface region (e.g., the interface region 304) that joins with the multi-layer film structure.

In FIG. 3B, and as described in greater detail in connection with FIGS. 5A-5F, the conductive structures 248 and 252 are formed using a dual damascene process. As shown in FIG. 3B, the semiconductor device (e.g., the device 200) includes a conductive layer (e.g., the conductive structure 244). The semiconductor device includes one or more dielectric layers (e.g., the dielectric layers 222 and 226) over the conductive layer. The semiconductor device includes a multi-layer film structure (e.g., a multi-layer film structure 302) that conforms to a dual damascene profile (a dual damascene profile of the conductive structures 248 and 252) within the one or more dielectric layers. The multi-layer film structure includes one or more barrier layers (e.g., the barrier layers 302a-302c) and a copper seed layer (e.g., the seed layer 302d) on the one or more barrier layers. The semiconductor device includes a copper structure (e.g., the conductive structure 248 and/or the conductive structure 252) that is adjacent to the multi-layer film structure and that includes a chlorine-enriched interface region (e.g., the interface region 304) that joins with the multi-layer film structure.

As shown in FIG. 3B, the conductive structure 248 may be a lower portion of a conductive structure and the conductive structure 252 may be an upper portion of the conductive structure. In some implementations, the conductive structure 248 may correspond to an interconnect structure and the conductive structure 252 may correspond to a conductive line. In some implementations, the conductive structures 248 and 252 are included in a middle end of line region of device 200. In some implementations, the conductive structures 248 and 252 are included in a backend of line region of the device 200.

As indicated above, FIGS. 3A and 3B are provided as examples. Other examples may differ from what is described with regard to FIGS. 3A and 3B.

FIGS. 4A-4G are diagrams of an example semiconductor manufacturing process 400 used to form conductive structures described herein. The semiconductor manufacturing process 400 may be performed by one or more of the semiconductor processing tools 102-114 and/or the wafer/die transport tool 116 to form the conductive structures 248 and 252 described in connection with FIG. 3A. Furthermore, the semiconductor manufacturing process 400 includes operations associated with a single damascene process.

FIG. 4A shows a side view of a portion of the device 200 that includes the conductive structure 244 formed in the ESL 216 and the dielectric layer 226. As shown in FIG. 4A, the ESL 220, the dielectric layer 222, and the ESL 224 are formed over and/or on the conductive structure 244. The deposition tool 102 may deposit the ESL 220, the dielectric layer 222, and/or the ESL 224 in a PVD operation, an ALD operation, a CVD operation, an epitaxy operation, an oxidation operation, a plating operation, another type of deposition operation described in connection with FIG. 1A and/or FIG. 1B, and/or another suitable deposition operation. In some implementations, the planarization tool 110 planarizes the ESL 220, the dielectric layer 222, and/or the ESL 224 after the deposition tool 102 deposits the ESL 220, the dielectric layer 222, and/or the ESL 224.

Turning to FIG. 4B, a recess 402 is formed in through the ESL 224, the dielectric layer 222, and the ESL 220 to the conductive structure 244. As shown in FIG. 4B, a pattern in a photoresist layer 404 is used to etch the recess 402 to form the recess 402. In these implementations, the deposition tool 102 forms the photoresist layer 404 on the ESL 220. The exposure tool 104 exposes the photoresist layer 404 to a radiation source to pattern the photoresist layer 404. The developer tool 106 develops and removes portions of the photoresist layer 404 to expose the pattern. The etch tool 108 etches the ESL 224, the dielectric layer 222, and the ESL 220 based on the pattern to form the recess 402. In some implementations, the etch operation includes a plasma etch operation, a wet chemical etch operation, and/or another type of etch operation. In some implementations, a photoresist removal tool removes the remaining portions of the photoresist layer 404 (e.g., using a chemical stripper, plasma ashing, and/or another technique). In some implementations, a hard mask layer is used as an alternative technique for etching the recess 402 based on a pattern.

As shown in FIG. 4C, the multi-layer film structure 302 (e.g., the multi-layer film structure 302 including the barrier layers 302a-302c and the seed layer 302d) is formed over and/or on the ESL 224 and along contours of the recess 402. The deposition tool 102 may sequentially deposit layers of the multi-layer film structure 302 in a PVD operation, an ALD operation, a CVD operation, a plating operation, an epitaxy operation, an oxidation operation, another type of deposition operation described in connection with FIG. 1A and/or FIG. 1B, and/or another suitable deposition operation. In some implementations, the planarization tool 110 planarizes layers of the multi-layer film structure 302 after the deposition tool 102 deposits the layers.

Turning to FIG. 4D, a chlorine-based pre-layer 406 including the chlorine molecules 146 is formed on the multi-layer film structure 302 (e.g., on the seed layer 302d). In some implementations, and as described in connection with FIG. 318, the chlorine-based pre-layer 406 is formed on the multi-layer film structure 302 as the multi-layer film structure 302 is submerged in a plating solution that includes the chlorine molecules 146 (e.g., the plating solution 138). Alternatively, a dispense tool may dispense or spray the chlorine-based pre-layer 406.

As shown in FIG. 4E, a conductive layer 408 (e.g., a copper layer) including the chlorine-enriched interface region 304 is formed over and/or on the multi-layer film structure 302. In some implementations, the plating tool 112 forms the conductive layer 408 including the chlorine-enriched interface region 304 using an electroplating operation described above in connection with FIGS. 1 and 2, and/or another suitable deposition operation. During the electroplating operation, a copper chelate material may form within the chlorine-enriched interface region 304.

In FIG. 4F, a planarization operation may be performed to remove portions of the conductive layer 408 to form the conductive structure 248. In some implementations, the planarization tool 110 performs a CMP operation to remove portions of the conductive layer 408. As formation of the conductive structure 248 included a single patterning and etching operation as described in connection with FIG. 4B, the conductive structure 248 may correspond to a single damascene structure.

As shown in FIG. 4G, and by repeating one or more of the operations described in connection with FIGS. 4A-4F (including photolithography, etching, and planarization operations), the conductive structure 252 (e.g., another single damascene structure) may be formed over the conductive structure 248. As shown in FIG. 4G, and as a result of the single damascene operations used to form the conductive structures 248 and 252, one or more portions 410 of the multi-layer film structure 302 and/or the interface region 304 may be between the conductive structures 248 and 252.

As indicated above, the semiconductor manufacturing process 400 of FIGS. 4A-4G is provided as an example. Other examples may differ from what is described with regard to FIGS. 4A-4G.

FIGS. 5A-5G are diagrams of an example semiconductor manufacturing process 500 used to form conductive structures described herein. The semiconductor manufacturing process 500 may be performed by one or more of the semiconductor processing tools 102-114 and/or the wafer/die transport tool 116 to form the conductive structures 248 and 252 described in connection with FIG. 3B. Furthermore, the semiconductor manufacturing process 500 includes operations associated with a dual damascene process.

FIG. 5A shows a side view of a portion of the device 200 that includes the conductive structure 244 formed in the ESL 216 and the dielectric layer 226. As shown in FIG. 5A, the ESL 220, the dielectric layer 222, the ESL 224, and the dielectric layer 226 are formed over and/or on the conductive structure 244. The deposition tool 102 may deposit the ESL 220, the dielectric layer 222, the ESL 224, and the dielectric layer 226 in a PVD operation, an ALD operation, a CVD operation, an epitaxy operation, an oxidation operation, a plating operation, another type of deposition operation described in connection with FIG. 1A and/or FIG. 1B, and/or another suitable deposition operation. In some implementations, the planarization tool 110 planarizes the ESL 220, the dielectric layer 222, the ESL 224, and the dielectric layer 226 after the deposition tool 102 deposits the ESL 220, the dielectric layer 222, the ESL 224, and the dielectric layer 226.

Turning to FIG. 5B, a recess 502 is formed in through the dielectric layer 226, the ESL 224, the dielectric layer 222, and the ESL 220 to the conductive structure 244. As shown in FIG. 5B, a pattern in a photoresist layer 504 is used to etch the recess 502 to form the recess 502. In these implementations, the deposition tool 102 forms the photoresist layer 504 on the dielectric layer 226. The exposure tool 104 exposes the photoresist layer 504 to a radiation source to pattern the photoresist layer 504. The developer tool 106 develops and removes portions of the photoresist layer 504 to expose the pattern. The etch tool 108 etches the dielectric layer 226, the ESL 224, the dielectric layer 222, and the ESL 220 based on the pattern to form the recess 502. In some implementations, the etch operation includes a plasma etch operation, a wet chemical etch operation, and/or another type of etch operation. In some implementations, a photoresist removal tool removes the remaining portions of the photoresist layer 504 (e.g., using a chemical stripper, plasma ashing, and/or another technique). In some implementations, a hard mask layer is used as an alternative technique for etching the recess 502 based on a pattern.

As shown in FIG. 5C, a recess 506 is formed in through the dielectric layer 226. As shown in FIG. 5C, a pattern in a photoresist layer 508 is used to etch the recess 506 to the ESL 224. In these implementations, the deposition tool 102 forms the photoresist layer 508 on the dielectric layer 226. The exposure tool 104 exposes the photoresist layer 508 to a radiation source to pattern the photoresist layer 508. The developer tool 106 develops and removes portions of the photoresist layer 508 to expose the pattern. The etch tool 108 etches the dielectric layer 226 based on the pattern to form the recess 506. In some implementations, the etch operation includes a plasma etch operation, a wet chemical etch operation, and/or another type of etch operation. In some implementations, a photoresist removal tool removes the remaining portions of the photoresist layer 508 (e.g., using a chemical stripper, plasma ashing, and/or another technique). In some implementations, a hard mask layer is used as an alternative technique for etching the recess 506 based on a pattern. In FIG. 5C, the recess 502 and the recess 506 may combine and/or merge to form a single recess having a stepped profile.

As shown in FIG. 5D, the multi-layer film structure 302 (e.g., the multi-layer film structure 302 including the barrier layers 302a-302c and the seed layer 302d) is formed over and/or on the dielectric layer 226 and along contours of the recess having the stepped profile (e.g., the combined recesses 502 and 506). The deposition tool 102 may sequentially deposit layers of the multi-layer film structure 302 in a PVD operation, an ALD operation, a CVD operation, a plating operation, an epitaxy operation, an oxidation operation, another type of deposition operation described in connection with FIG. 1A and/or FIG. 1B, and/or another suitable deposition operation. In some implementations, the planarization tool 110 planarizes layers of the multi-layer film structure 302 after the deposition tool 102 deposits the layers.

Turning to FIG. 5E, a chlorine-based pre-layer 406 including the chlorine molecules 146 is formed on the multi-layer film structure 302 (e.g., on the seed layer 302d). In some implementations, and as described in connection with FIG. 218, the chlorine-based pre-layer 406 is formed on the multi-layer film structure 302 as the multi-layer film structure 302 is submerged in a plating solution that includes the chlorine molecules 146 (e.g., the plating solution 138). Alternatively, a dispense tool may dispense or spray the chlorine-based pre-layer 406.

As shown in FIG. 5F, a conductive layer 510 (e.g., a copper layer) including the chlorine-enriched interface region 304 is formed over and/or on the multi-layer film structure 302. In some implementations, the plating tool 112 forms the conductive layer 510 including the chlorin-enriched interface region 304 using an electroplating operation described above in connection with FIGS. 1A and 1B, and/or another suitable deposition operation. During the electroplating operation, a copper chelate material may form within the chlorine-enriched interface region 304.

In FIG. 5G, a planarization operation may be performed to remove portions of the conductive layer 510 to form a conductive structure (e.g., a conductive structure including a combination of the conductive structures 248 and 252). In some implementations, the planarization tool 110 performs a CMP operation to remove portions of the conductive layer 510. As formation of the conductive structure included a dual patterning and etching operations as described in connection with FIGS. 5B and 5C, the conductive structure may correspond to a dual damascene structure.

As indicated above, the semiconductor manufacturing process 500 of FIGS. 5A-5G is provided as an example. Other examples may differ from what is described with regard to FIGS. 5A-5G.

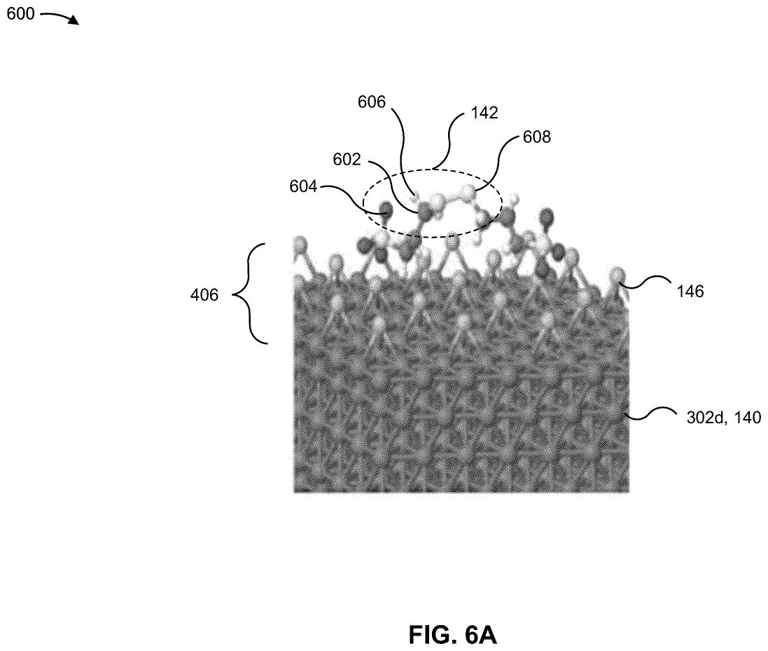

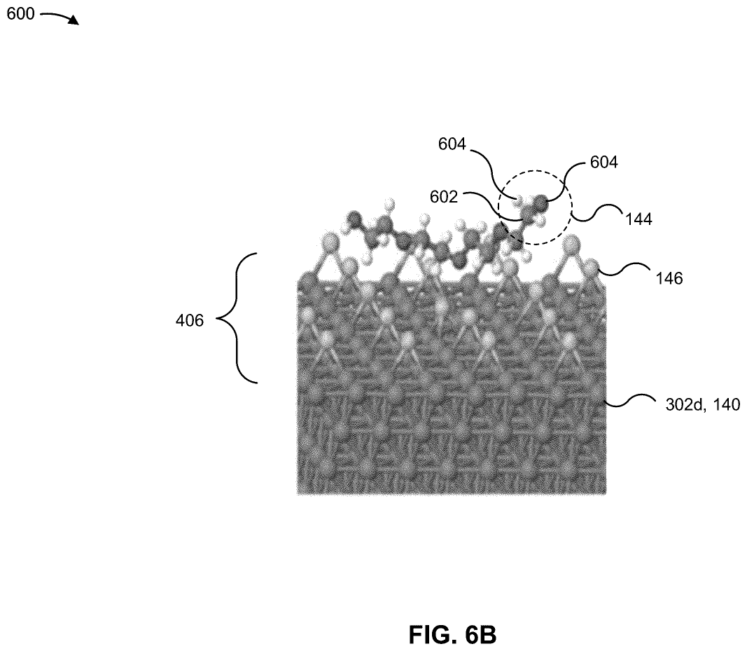

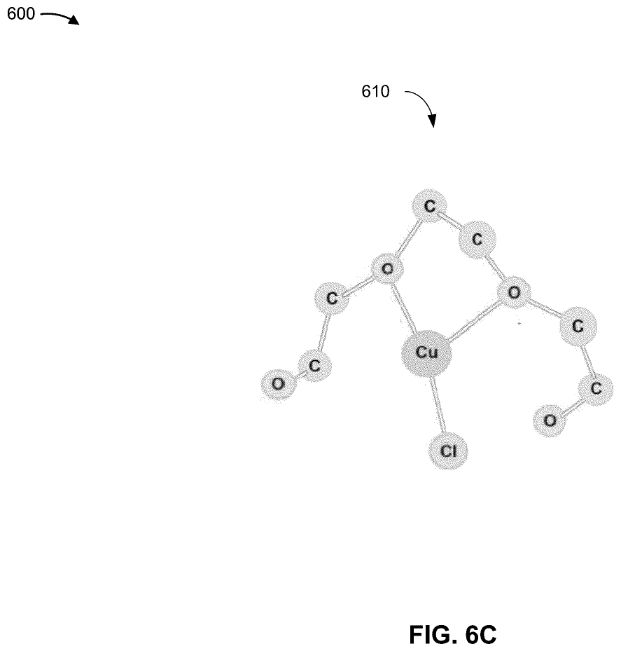

FIGS. 6A-6C are diagrams of an example details 600 related to formation of a chlorine-enriched interface region described herein. The chlorine-enriched interface region may correspond to the chlorine-enriched interface region 304 formed using a plating solution (e.g., the plating solution 138 of FIG. 1B) including the plating material 140, the accelerator additive 142, and the suppressor additive 144.

FIG. 6A shows an example molecular arrangement of the chlorine-based pre-layer 406 including the chlorine molecules 146 over the seed layer 302d (e.g., a copper seed layer). In some implementations, the plating solution may include a concentration of the accelerator additive 142. As shown in FIG. 6A, the accelerator additive 142 may correspond to an SPS additive with a molecular structure that includes carbon (C) atoms (602), oxygen (O) atoms 604, hydrogen (H) atoms 606, and sulfur(S) atoms 608. In some implementations, the accelerator additive 142 reduces a grain size and/or a surface roughness of the plating material 140 to increase a rate of electroplating (e.g., growth of the plating material 140 on the seed layer 302d). Additionally, or alternatively, as a concentration (e.g., molecular coverage) of the accelerator additive 142 increases, an absorptivity and/or a concentration of the chlorine molecules 146 within an electroplated region on the seed layer 302d (e.g., in chlorine-enriched interface region 304) may increase.

FIG. 6B shows an example molecular arrangement of the chlorine-based pre-layer 406 including the chlorine molecules 146 over the seed layer 302d (e.g., a copper seed layer). In some implementations, the plating solution may include a concentration of the suppressor additive 144. As shown in FIG. 6B, the suppressor additive 144 may correspond to a PEG additive with a molecular structure that includes carbon (C) atoms 602, oxygen (O) atoms 604, and hydrogen (H) atoms 606. In some implementations, the suppressor additive 144 may reduce a surface tension in the plating solution to increase a rate of electroplating (e.g., growth of the plating material 140 on the seed layer 302d). Additionally, or alternatively, as a concentration (e.g., molecular coverage) of the suppressor additive 144 increases, an absorptivity and/or a concentration of the chlorine molecules 146 within an electroplated region on the seed layer 302d (e.g., in chlorine-enriched interface region 304) may increase.

FIG. 6C shows an example copper chelate material 610 that may be found in a chlorine-enriched interface region (e.g., the chlorine-enriched interface region 304). As shown in FIG. 6C, a possible arrangement of impurities in the copper chelate material 610 includes chlorine (Cl) impurities (e.g., Cl from the chlorine molecules 146). The possible arrangement of impurities further includes carbon (C) impurities and oxygen (O) impurities (e.g., C impurities and O impurities from an SPS accelerator and/or a PEG suppressor).

As an example, a concentration of Cl impurities in the copper chelate material 610 may be included in a range of range of approximately 1×10¹⁸ atoms per cubic centimeter to approximately 1×10²⁰ atoms per cubic centimeter. If the concentration of the Cl impurities within the copper chelate material 610 is less than approximately 1×10¹⁸ atoms per cubic centimeter, chelation may be incomplete and an interface region including the copper chelate material (e.g., the chlorine-enriched interface region 304) may be ineffective at preventing electromigration and/or stress migration defects within a semiconductor device. If the concentration of the Cl impurities within the copper chelate material 610 is greater than approximately 1×10²⁰ atoms per cubic centimeter, excessive chelation may have occurred to increase an electrical resistance of a copper structure including the copper chelate material 610 (e.g., the conductive structure 248 and/or the conductive structure 252 including the chlorine-enriched interface region 304). However, other values and ranges for the concentration of Cl impurities in the copper chelate material 610 (and/or the chlorine-enriched interface region 304) are within the scope of the present disclosure.

Additionally, or alternatively, a ratio of a concentration of Cl impurities to a concentration of copper (Cu) atoms within the copper chelate material 610 may be greater than approximately 1:100. If the ratio of Cl impurities to Cu atoms within the copper chelate material 610 is less than approximately 1:100, chelation may be incomplete and the copper chelate material 610 (e.g., the chlorine-enriched interface region 304) may be ineffective at preventing electromigration and/or stress migration defects within a semiconductor device including the copper chelate material 610 (e.g., the device 200). However, other values and ranges for the ratio of Cl impurities to Cu atoms within the copper chelate material 610 (and/or the chlorine-enriched interface region 304) are within the scope of the present disclosure.

As indicated above, FIGS. 6A-6C are provided as examples. Other examples may differ from what is described with regard to FIGS. 6A-6C.

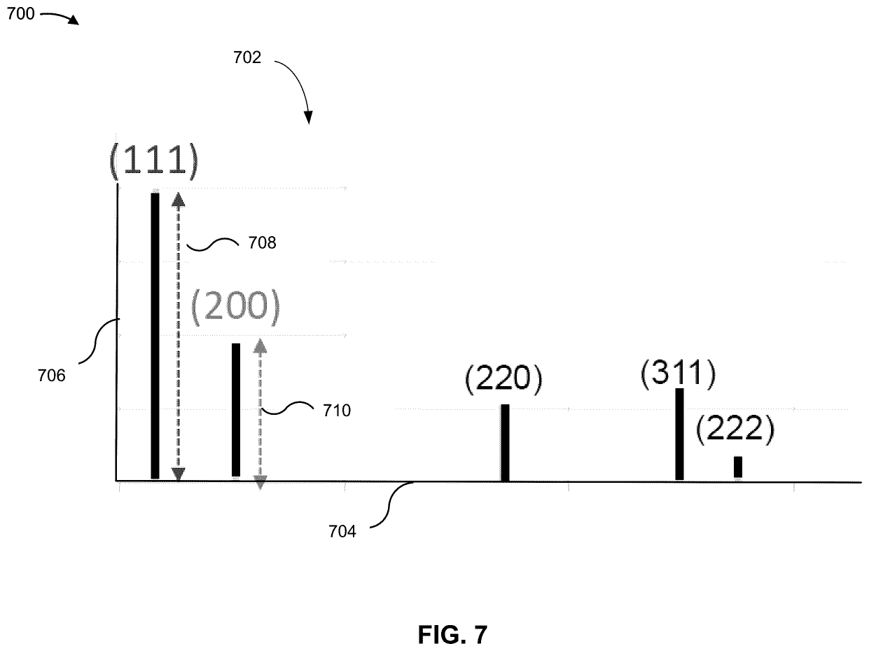

FIG. 7 is a diagram of an example copper pattern 700 within a chlorine-enriched interface region described herein. In some implementations, the copper pattern 700 corresponds to a copper pattern within the chlorine-enriched interface region 304.

The x-ray diffraction (XRD) analysis chart 702 showing the copper pattern 700 includes a position axis 704 indicating a θ/2θ angular position of a refraction detector and an intensity axis 706 indicating a count of refracted x-rays at the angular position during an XRD scan. The XRD analysis chart 702 can be used to associate a lattice structure (e.g., a Miller index of a lattice) within the copper pattern 700 to different angular positions across the scan.

As shown in the XRD analysis chart 702, the copper pattern 700 includes different intensities (e.g., quantities) of copper lattice structures corresponding to <111>, <200>, <220>, <311>, and <222> at different scanned positions within the chlorine-enriched interface region 304. Further, and as shown in the XRD analysis chart 702, the copper lattice structures <111> have an XRD peak intensity 708 and the copper lattices structures <200> have an XRD peak intensity 710. As shown in FIG. 7, and for the copper pattern 700, an x-ray diffraction peak intensity ratio of the <111> copper lattice structures to the <200> lattice structures may be included in a range of approximately 9:5 to approximately 11:5. If the ratio is less than approximately 9:5, then a uniformity and/or a quality of a structure formed using the copper pattern 700 may not satisfy a threshold due to insufficient electron migration during formation of the structure (e.g., the structure may have “thin” regions). If the ratio is greater than approximately 11:5, then a uniformity and/or a quality of a structure formed using the copper pattern 700 may not satisfy a threshold due to excessive electron migration during formation of the structure (e.g., the structure may have “thick” regions). However, other values and ranges for the peak intensity ratio are within the scope of the present disclosure.

As indicated above, FIG. 7 is provided as an example. Other examples may differ from what is described with regard to FIG. 7.

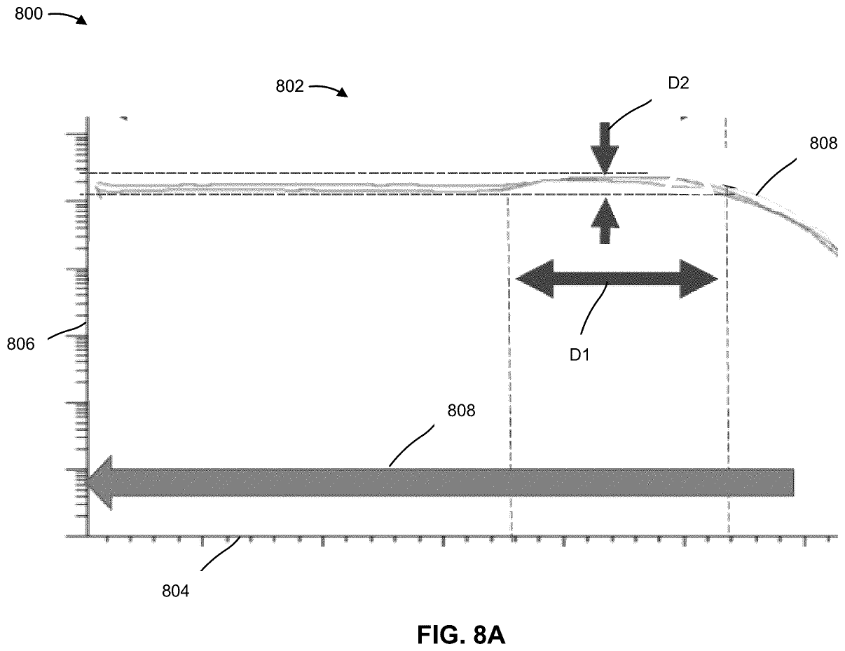

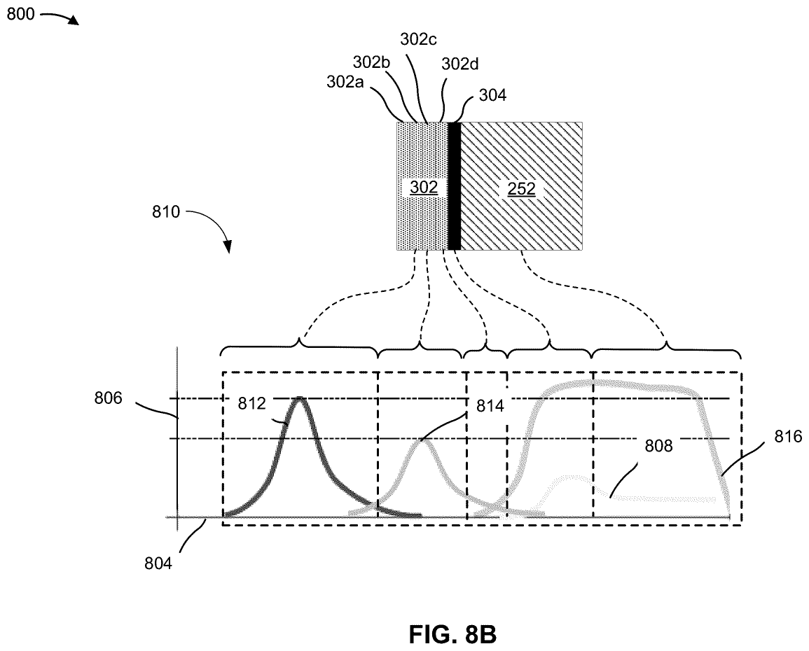

FIGS. 8A and 8B are diagrams of an example implementation 800 described herein. The example implementation 800 quantifies concentrations of one or more elements used in formation of the chlorine-enriched interface region 304 on the multi-layer film structure 302, including elements associated with the plating solution 138 described in connection with FIG. 1B.

The chart 802 in FIG. 8A includes a position axis 804 (e.g., position in nanometers) and a concentration axis 806 (e.g., concentration in atoms per cubic centimeter). The position axis may include a thickness D1 of an interface region with a concentration of chlorine 808 (e.g., the chlorine-enriched interface region 304). In some implementations, the thickness D1 may be included in a range of approximately 30 nanometers to approximately 150 nanometers. If the thickness is less than approximately 30 nanometers, the region may be ineffective at preventing electromigration and/or stress migration defects in the semiconductor device. If the thickness D1 is greater than approximately 150 nanometers, the region may have an increased electrical resistance. Further, a variation D2 in the concentration of chlorine 808 may be included in a range of approximately 1×10¹⁸ atoms per cubic centimeter to approximately 1×10²⁰ atoms per cubic centimeter. However, other values and ranges for the thickness D1, and the variation D2, are within the scope of the present disclosure.

The chart 810 in FIG. 8B shows an example variation in concentrations of elements includes in the multi-layer film structure 302, the chlorine-enriched interface region 304, and the conductive structure 252. As shown in FIG. 8B, the barrier layer 302b may include a concentration of tantalum 812 and a concentration of cobalt 814. Additionally, or alternatively, the seed layer 302d may include a concentration of chlorine 808, a concentration of cobalt 814, and/or a concentration of copper 816. Additionally, or alternatively and as shown in FIG. 8B, the chlorine-enriched interface region 304 may include a concentration of chlorine 808, a concentration of cobalt 814, and/or a concentration of copper 816. Additionally, or alternatively and as shown in FIG. 8B, the conductive structure 252 may include a concentration of chlorine 808 and a concentration of copper 816.

Based on a concentration of chlorine 808 within the chlorine-enriched interface region 304, a magnitude of an energy absorption level may be increased relative to an interface region including pure copper. The increased magnitude of the energy absorption level may reduce a likelihood of diffusion of the copper ions (through either electromigration (EM) or stress migration (SM)) through the multi-layer film structure 302 and to other metallization layers of the semiconductor device (e.g., MEOL metallization layers and/or FEOL metallization layers).

As indicated above, FIGS. 8A and 8B are provided as examples. Other examples may differ from what is described with regard to FIGS. 8A and 8B.

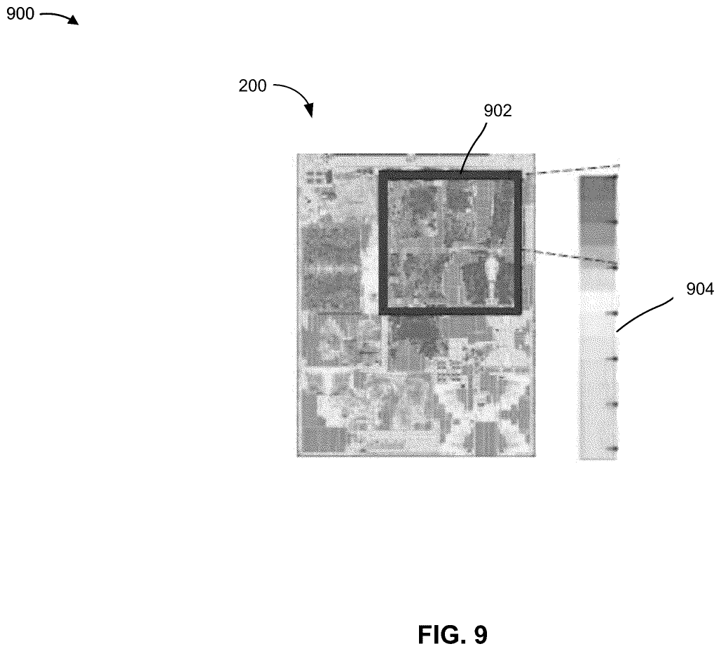

FIG. 9 is a diagram of an example implementation 900 described herein. In the implementation 900, a region of the device 200 includes a zone 902 populated with features having an aggregate lateral surface area 904 (line edge X depth value, or LED value) that is greater relative to other zones of the device 200. The zone 902 may be referred to as a “High LED Zone”, and be prone to void defects and/or edge fill defects. For conductive structures located in this zone, a factor such as a current density may dominate electroplating gap fill performance (e.g., a relatively low current density may cause voids and/or defects in structures formed by the electroplating process).

Using techniques described herein (e.g., forming the chlorine-enriched interface region 304 as part of forming one or more conductive structures), a filling of gaps and/or voids within the zone 902 may be improved to reduce defects within the device 200.

As indicated above, FIG. 9 is provided as an example. Other examples may differ from what is described with regard to FIG. 9.

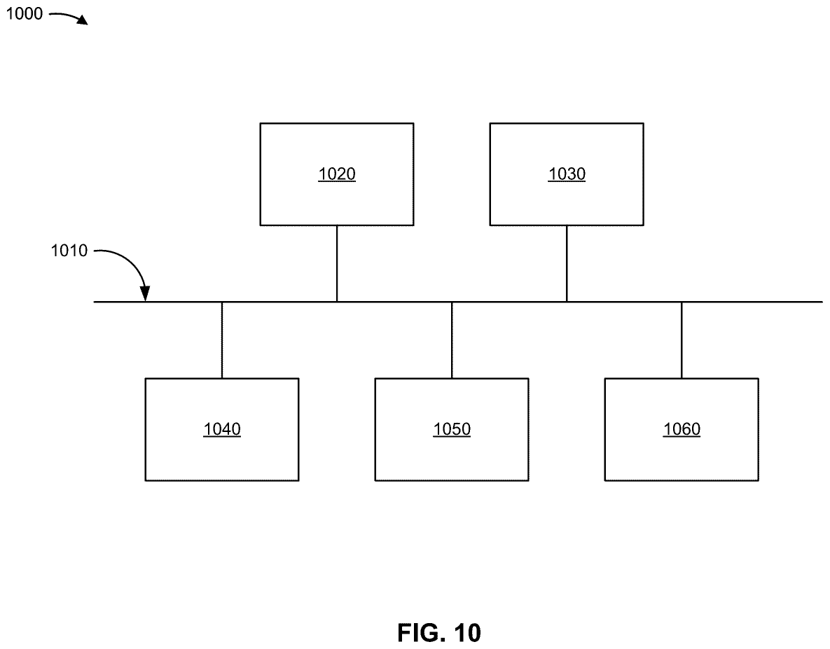

FIG. 10 is a diagram of example components of a device 1000 described herein. The device 1000 may correspond to one or more of the semiconductor processing tools 102-114 and/or the wafer/die transport tool 116. In some implementations, one or more of the semiconductor processing tools 102-114 and/or the wafer/die transport tool 116 may include one or more devices 1000 and/or one or more components of the device 1000. As shown in FIG. 10, the device 1000 may include a bus 1010, a processor 1020, a memory 1030, an input component 1040, an output component 1050, and/or a communication component 1060.

The bus 1010 may include one or more components that enable wired and/or wireless communication among the components of the device 1000. The bus 1010 may couple together two or more components of FIG. 10, such as via operative coupling, communicative coupling, electronic coupling, and/or electric coupling. For example, the bus 1010 may include an electrical connection (e.g., a wire, a trace, and/or a lead) and/or a wireless bus. The processor 1020 may include a central processing unit, a graphics processing unit, a microprocessor, a controller, a microcontroller, a digital signal processor, a field-programmable gate array, an application-specific integrated circuit, and/or another type of processing component. The processor 1020 may be implemented in hardware, firmware, or a combination of hardware and software. In some implementations, the processor 1020 may include one or more processors capable of being programmed to perform one or more operations or processes described elsewhere herein.

The memory 1030 may include volatile and/or nonvolatile memory. For example, the memory 1030 may include random access memory (RAM), read only memory (ROM), a hard disk drive, and/or another type of memory (e.g., a flash memory, a magnetic memory, and/or an optical memory). The memory 1030 may include internal memory (e.g., RAM, ROM, or a hard disk drive) and/or removable memory (e.g., removable via a universal serial bus connection). The memory 1030 may be a non-transitory computer-readable medium. The memory 1030 may store information, one or more instructions, and/or software (e.g., one or more software applications) related to the operation of the device 1000. In some implementations, the memory 1030 may include one or more memories that are coupled (e.g., communicatively coupled) to one or more processors (e.g., processor 1020), such as via the bus 1010. Communicative coupling between a processor 1020 and a memory 1030 may enable the processor 1020 to read and/or process information stored in the memory 1030 and/or to store information in the memory 1030.

The input component 1040 may enable the device 1000 to receive input, such as user input and/or sensed input. For example, the input component 1040 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1050 may enable the device 1000 to provide output, such as via a display, a speaker, and/or a light-emitting diode. The communication component 1060 may enable the device 1000 to communicate with other devices via a wired connection and/or a wireless connection. For example, the communication component 1060 may include a receiver, a transmitter, a transceiver, a modem, a network interface card, and/or an antenna.

The device 1000 may perform one or more operations or processes described herein. For example, a non-transitory computer-readable medium (e.g., memory 1030) may store a set of instructions (e.g., one or more instructions or code) for execution by the processor 1020. The processor 1020 may execute the set of instructions to perform one or more operations or processes described herein. In some implementations, execution of the set of instructions, by one or more processors 1020, causes the one or more processors 1020 and/or the device 1000 to perform one or more operations or processes described herein. In some implementations, hardwired circuitry may be used instead of or in combination with the instructions to perform one or more operations or processes described herein. Additionally, or alternatively, the processor 1020 may be configured to perform one or more operations or processes described herein. Thus, implementations described herein are not limited to any specific combination of hardware circuitry and software.

The number and arrangement of components shown in FIG. 10 are provided as an example. The device 1000 may include additional components, fewer components, different components, or differently arranged components than those shown in FIG. 10. Additionally, or alternatively, a set of components (e.g., one or more components) of the device 1000 may perform one or more functions described as being performed by another set of components of the device 1000.

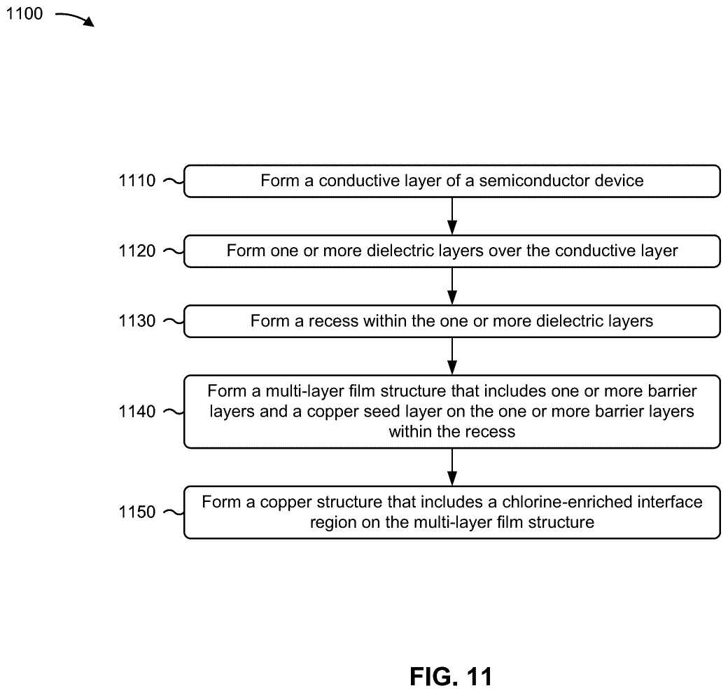

FIG. 11 is a flowchart of an example process 1100 associated with copper plating in a semiconductor device. In some implementations, one or more process blocks of FIG. 11 are performed by one or more semiconductor processing tools (e.g., one or more of the semiconductor processing tools 102-114 and/or the wafer/die transport tool 116). Additionally, or alternatively, one or more process blocks of FIG. 11 may be performed by one or more components of device 1000, such as processor 1020, memory 1030, input component 1040, output component 1050, and/or communication component 1060.

As shown in FIG. 11, process 1100 may include forming a conductive layer of a semiconductor device (block 1110). For example, one or more of the semiconductor processing tools 102-114 may form a conductive layer of a semiconductor device (e.g., the M0 metallization layer that includes the conductive structure 244), as described herein.

As further shown in FIG. 11, process 1100 may include forming one or more dielectric layers over the conductive layer (block 1120). For example, one or more of the semiconductor processing tools 102-114 and/or the wafer/die transport tool 116 may form one or more dielectric layers (e.g., the dielectric layers 222 and 226) over the conductive layer, as described herein.

As further shown in FIG. 11, process 1100 may include forming a recess within the one or more dielectric layers (block 1130). For example, one or more of the semiconductor processing tools 102-114 and/or the wafer/die transport tool 116 may form a recess (e.g., the recess 402, the recess 502, and/or the recess 506) within the one or more dielectric layers, as described herein.

As further shown in FIG. 11, process 1100 may include forming a multi-layer film structure that includes one or more barrier layers and a copper seed layer on the one or more barrier layers within the recess (block 1140). For example, one or more of the semiconductor processing tools 102-114 and/or the wafer/die transport tool 116 may form a multi-layer film structure (e.g., the multi-layer film structure 302) that includes one or more barrier layers (e.g., the barrier layers 302a-302c) and a copper seed layer (e.g., the seed layer 302d) on the one or more barrier layers within the recess, as described herein.

As further shown in FIG. 11, process 1100 may include forming a copper structure that includes a chlorine-enriched interface region on the multi-layer film structure (block 1150). For example, one or more of the semiconductor processing tools 102-114 and/or the wafer/die transport tool 116 may form a copper structure (e.g., the conductive structure 248 and/or the conductive structure 252) that includes a chlorine-enriched interface region (e.g., the chlorine-enriched interface region 304) on the multi-layer film structure, as described herein.

Process 1100 may include additional implementations, such as any single implementation or any combination of implementations described below and/or in connection with one or more other processes described elsewhere herein.

In a first implementation, forming the recess includes forming a recess having a single damascene profile.

In a second implementation, alone or in combination with the first implementation, forming the recess includes forming a recess having a dual damascene profile.

In a third implementation, alone or in combination with one or more of the first and second implementations, forming the copper structure including the chlorine-enriched interface region on the multi-layer film structure includes forming a chlorine-based pre-layer (e.g., the chlorine-based pre-layer 406) on the copper seed layer.

In a fourth implementation, alone or in combination with one or more of the first through third implementations, forming the copper structure including the chlorine-enriched interface region on the multi-layer film structure includes performing a copper electroplating process that chelates copper using the chlorine-based pre-layer.

In a fifth implementation, alone or in combination with one or more of the first through fourth implementations, forming the chlorine-based pre-layer on the copper seed layer includes dispensing a liquid solution that includes chlorine on the copper seed layer.

In a sixth implementation, alone or in combination with one or more of the first through fifth implementations, forming the chlorine-based pre-layer on the copper seed layer includes using a liquid solution including a polyethylene glycol suppressor (e.g., the suppressor additive 144) and a bis (3-sulfopropyl) disulfide accelerator (e.g., the accelerator additive 142).

In a seventh implementation, alone or in combination with one or more of the first through sixth implementations, forming the chlorine-based pre-layer on the copper seed layer includes passing a semiconductor substrate that includes the multi-layer film structure through a layer of chlorine (e.g., the chlorine molecules 146) suspended at a surface of a liquid solution (E.g., the plating solution 138).

In an eighth implementation, alone or in combination with one or more of the first through seventh implementations, passing the multi-layer film structure through the layer of chlorine suspended at the surface of a liquid solution includes varying a rate at which the semiconductor substrate passes through the layer of chlorine to satisfy an electromigration threshold or to satisfy a stress migration threshold.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

Some implementations described herein provide techniques and apparatuses for forming a copper structure adjacent to a multi-layer film structure included in a semiconductor device. The techniques include using an electroplating process to form the copper structure adjacent to the multi-layer film structure, where a pre-layer of chlorine molecules coats a seed layer of the multi-layer film structure during the electroplating process. During formation of the copper structure, a chlorine-enriched interface region (e.g., a control layer including a copper chelate material enriched with chlorine) may be formed between the copper structure and the multi-layer film structure including the seed layer.

Based on a presence of the chlorine molecules within the interface region, a magnitude of an energy absorption level may be increased relative to an interface region including pure copper. The increased magnitude of the energy absorption level may reduce a likelihood of diffusion of the copper ions (through either electromigration (EM) or stress migration (SM)) through the multi-layer film structure and to other metallization layers of the semiconductor device (e.g., MEOL metallization layers and/or FEOL metallization layers). Additionally, or alternatively and during formation of the copper structure, the presences of the chlorine-enriched interface region may improve electromigration of copper ions within the copper structure to reduce voids and/or defects within the copper structure.

In this way, a likelihood of unintended migration of copper ions from the copper structure to MEOL and/or BEOL structures may be reduced to increase an electrical performance of the semiconductor device. Additionally, or alternatively, a likelihood of voids and/or defects within the copper structure may be reduced to increase a reliability of the semiconductor device. As such, an amount of resources used to manufacture a volume of the semiconductor device satisfying a performance and reliability threshold (semiconductor processing tools, raw materials, manpower, and/or computing resources, among other examples) may be reduced.

As described in greater detail above, some implementations described herein provide a semiconductor device. The semiconductor device includes a conductive layer. The semiconductor device includes one or more dielectric layers over the conductive layer. The semiconductor device includes a multi-layer film structure that conforms to a single damascene profile within the one or more dielectric layers. The multi-layer film structure includes one or more barrier layers and a copper seed layer on the one or more barrier layers. The semiconductor device includes a copper structure that is adjacent to the multi-layer film structure and that includes a chlorine-enriched interface region that joins with the multi-layer film structure.

As described in greater detail above, some implementations described herein provide a semiconductor device. The semiconductor device includes a conductive layer. The semiconductor device includes one or more dielectric layers over the conductive layer. The semiconductor device includes a multi-layer film structure that conforms to a dual damascene profile within the one or more dielectric layers. The multi-layer film structure includes one or more barrier layers and a copper seed layer on the one or more barrier layers. The semiconductor device includes a copper structure that is adjacent to the multi-layer film structure and that includes a chlorine-enriched interface region that joins with the multi-layer film structure.

As described in greater detail above, some implementations described herein provide a method. The method includes forming a conductive layer of a semiconductor device. The method includes forming one or more dielectric layers over the conductive layer. The method includes forming a recess within the one or more dielectric layers. The method includes forming a multi-layer film structure that includes one or more barrier layers and a copper seed layer on the one or more barrier layers within the recess. The method includes forming a copper structure including a chlorine-enriched interface region on the multi-layer film structure.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a conductive layer;
one or more dielectric layers over the conductive layer;
a multi-layer film structure that conforms with a single damascene profile within the one or more dielectric layers and that comprises:
one or more barrier layers;
a copper seed layer on the one or more barrier layers; and
a copper structure adjacent to the multi-layer film structure and comprising:
a chlorine-enriched interface region that joins with the multi-layer film structure.

2. The semiconductor device of claim 1, wherein the chlorine-enriched interface region comprises:
a copper chelate material.

3. The semiconductor device of claim 1, wherein the chlorine-enriched interface region comprises:
a thickness that is included in a range of approximately 30 nanometers to approximately 150 nanometers.

4. The semiconductor device of claim 1, wherein a ratio of a concentration of chlorine to a concentration of copper within the chlorine-enriched interface region is greater than approximately 1:100.

5. The semiconductor device of claim 1, wherein a concentration of chlorine within the chlorine-enriched interface region is included in a range of approximately 1×10¹⁸ atoms per cubic centimeter to approximately 1×10²⁰ atoms per cubic centimeter.

6. The semiconductor device of claim 1, wherein the one or more barrier layers comprise:
a layer of a silicon dioxide material,
a layer of a tantalum nitride material, or
a layer of a cobalt material.

7. A semiconductor device comprising:
a conductive layer;
one or more dielectric layers over the conductive layer;
a multi-layer film structure that conforms to a dual damascene profile within the one or more dielectric layers and comprises:
one or more barrier layers;
a copper seed layer on the one or more barrier layers; and
a copper structure adjacent to the multi-layer film structure and comprising:
a chlorine-enriched interface region that joins with the multi-layer film structure.

8. The semiconductor device of claim 7, wherein the copper structure comprises:
an upper portion corresponding to a conductive line within a backend of line region or a middle end of line region of the semiconductor device, and
a lower portion corresponding to an interconnect structure within the backend of line region or the middle end of line region of the semiconductor device.

9. The semiconductor device of claim 7, wherein the copper structure is located in a zone of the semiconductor device that is prone to void defects or edge fill defects due to a lateral surface area of the of the copper structure, and
wherein the chlorine-enriched interface region reduces a likelihood of the void defects or the edge fill defects within the zone.

10. The semiconductor device of claim 7, wherein the chlorine-enriched interface region comprises:
first copper lattice structures having a <111> miller index,
and second copper lattice structures having a <200> miller index.

11. The semiconductor device of claim 10, wherein an x-ray diffraction peak intensity ratio of the first copper lattice structures to the second copper lattice structures is included in a range of approximately 9:5 to approximately 11:5.

12. A method, comprising:
forming a conductive layer of a semiconductor device;
forming one or more dielectric layers over the conductive layer;
forming a first recess and a second recess within the one or more dielectric layers;
forming a multi-layer film structure that comprises one or more barrier layers and a copper seed layer along contours of the first recess and the second recess; and
forming a copper structure having a chlorine-enriched interface region on the multi-layer film structure.

13. The method of claim 12, wherein forming the first recess, the second recess, and the copper structure comprises:
forming the first recess, the second recess, and the copper structure using a single damascene process.

14. The method of claim 12, wherein forming the first recess, the second recess, and the copper structure comprises:
forming the first recess, the second recess, and the copper structure using a dual damascene process.

15. The method of claim 12, wherein forming the copper structure having the chlorine-enriched interface region on the multi-layer film structure comprises:
forming a chlorine-based pre-layer on the copper seed layer.

16. The method of claim 15, wherein forming the copper structure comprising the chlorine-enriched interface region on the multi-layer film structure comprises:
performing a copper electroplating process that chelates copper using the chlorine-based pre-layer.

17. The method of claim 15, wherein forming the chlorine-based pre-layer on the copper seed layer comprises:
dispensing a liquid solution that includes chlorine on the copper seed layer.

18. The method of claim 15, wherein forming the chlorine-based pre-layer on the copper seed layer comprises:
using a liquid solution comprising a polyethylene glycol suppressor and a bis (3-sulfopropyl) disulfide accelerator.

19. The method of claim 15, wherein forming the chlorine-based pre-layer on the copper seed layer comprises:
passing a semiconductor substrate that includes the multi-layer film structure through a layer of chlorine suspended at a surface of a liquid solution.

20. The method of claim 19, wherein passing the multi-layer film structure through the layer of chlorine suspended at the surface of a liquid solution comprises:
varying a rate at which the semiconductor substrate passes through the layer of chlorine to satisfy an electromigration threshold or to satisfy a stress migration threshold.
